(19) United States
(12) Patent Application Publication
(10) Pub. No.: US 2022/0013471 A1
(43) Pub. Date: Jan. 13, 2022

(54) IC PACKAGE

(71) Applicant: Yangtze Memory Technologies Co., Ltd., Wuhan (CN)

(72) Inventors: Houde ZHOU, Wuhan (CN); Peng CHEN, Wuhan (CN)

(73) Assignee: Yangtze Memory Technologies Co., Ltd., Wuhan (CN)

(21) Appl. No.: 17/448,821

(22) Filed: Sep. 24, 2021

Related U.S. Application Data
(62) Division of application No. 16/365,744, filed on Mar. 27, 2019.
Application No. 16/365,744 is a continuation of application No. PCT/CN2018/112567, filed on Oct. 30, 2018.

(51) Int. Cl. H01L 23/544; H01L 21/56; H01L 23/31; H01L 23/367; H01L 23/00; H01L 25/065; H01L 25/00

(52) U.S. Cl. CPC H01L 23/544; H01L 21/56; H01L 23/3128; H01L 23/367; H01L 24/48; H01L 2225/06562; H01L 25/50; H01L 2223/54433; H01L 2224/48227; H01L 2225/0651; H01L 25/0657

(57) ABSTRACT

In a method for fabricating an integrated circuit (IC) package, one or more IC chips are stacked on a package substrate. A marking plate is formed on the one or more IC chips with a first major surface facing the one or more IC chips. A plastic structure is formed to encapsulate the one or more IC chips and the marking plate such that a second major surface of the marking plate is a portion of an outer surface of the IC package.

### RELATED APPLICATION

This application is a divisional of U.S. patent application Ser. No. 16/365,744 filed on Mar. 27, 2019, which is a bypass continuation of International Application No. PCT/CN2018/112567, filed on Oct. 30, 2018. The entire contents of the above-identified applications are incorporated herein by reference in their entirety.

### BACKGROUND

In semiconductor manufacturing, integrated circuit (IC) packaging is a step in the semiconductor device fabrication that encapsulates one or more semiconductor dies (also referred to as IC chips) of integrated circuits in a supporting case that prevents physical damage, corrosion and the like. The supporting case with the encapsulated semiconductor die(s) is referred to as an IC package. The IC package can be laser-marked for identification and traceability.

### SUMMARY

Aspects of the disclosure provide an integrated circuit (IC) package. The IC package includes a package substrate, one or more IC chips, a marking plate and a plastic structure. The one or more IC chips are interconnected with the package substrate. The marking plate has a first major surface and a second major surface. The marking plate is stacked on the one or more IC chips with the first major surface facing the one or more IC chips. The plastic structure is configured to encapsulate the one or more IC chips and the marking plate with the second major surface of the marking plate being a portion of an outer surface of the IC package.

In some examples, the marking plate is formed of at least one of a semiconductor material, a ceramic material, a metal material, a metal alloy material. In an example, the marking plate is configured to have a stair structure, and the first major surface has a different surface area from (such as a smaller surface area than) the second major surface. In another example, the marking plate is configured to have a rectangular cuboid shape that the first major surface and the second major surface have the same surface area.

In an embodiment, the IC package includes a plurality of bond wires that are configured to interconnect the one or more IC chips to the package substrate. The plastic structure is configured to encapsulate the plurality of bond wires.

It is noted that the IC package is one of a ball grid array (BGA) package, a quad-flat package (QFP), a quad flat non-lead (QFN) package, a land grid array (LGA) package, and a pin grid array (PGA).

In some embodiments, neighboring IC chips are staggered and multiple IC chips in the IC package are stacked in a zig-zag pattern.

According to an aspect of the disclosure, the marking plate has a better anti-laser penetration property than the plastic structure. For example, a laser penetration depth in the marking plate is shorter than a laser penetration depth in the plastic structure. In some examples, the marking plate has a higher rigidity than the plastic structure. According to another aspect of the disclosure, the marking plate has a substantially equal coefficient thermal expansion (CTE) as the one or more IC chips. According to another aspect of the disclosure, the marking plate has a better thermal conductivity than the plastic structure. Thus, the marking plate can transfer heat generated by the IC chips during operation to the outer surface of the IC package.

Aspects of the disclosure provide a method for fabricating an integrated circuit (IC) package. The method includes stacking one or more IC chips on a package substrate, stacking a marking plate on the one or more IC chips with a first major surface facing the one or more IC chips, and forming a plastic structure that encapsulates the one or more IC chips and the marking plate with a second major surface of the marking plate being a portion of an outer surface of the IC package.

In an example, the method includes encapsulating the marking plate and the one or more IC chips in the plastic structure, and grinding the plastic structure to expose the second major surface of the marking plate. Further, the method includes laser-marking on the second major surface of the marking plate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a cross-sectional view of an integrated circuit (IC) package 100 in accordance with some embodiments.

FIG. 2 shows a cross-sectional view of another IC package 200 in accordance with some embodiments.

FIG. 3 shows a flow chart outlining a process example 300 according to an embodiment of the disclosure.

FIGS. 4-6 show cross-sectional views of the IC package 100 during a fabrication process in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Aspects of the disclosure provide an integrated circuit (IC) package with a marking plate embedded in a plastic structure. The marking plate has a higher rigidity than the molding material of the plastic structure, and has a better anti-laser penetration property than the molding material. Because of the higher rigidity, the IC package distortion due to high temperature processing, such as a soldering process, can be reduced. Further, because of the better anti-laser penetration property, a relatively thinner marking plate is allowed. Thus, the IC package can have a relatively small thickness or can encapsulate more IC chips without increasing the package thickness.

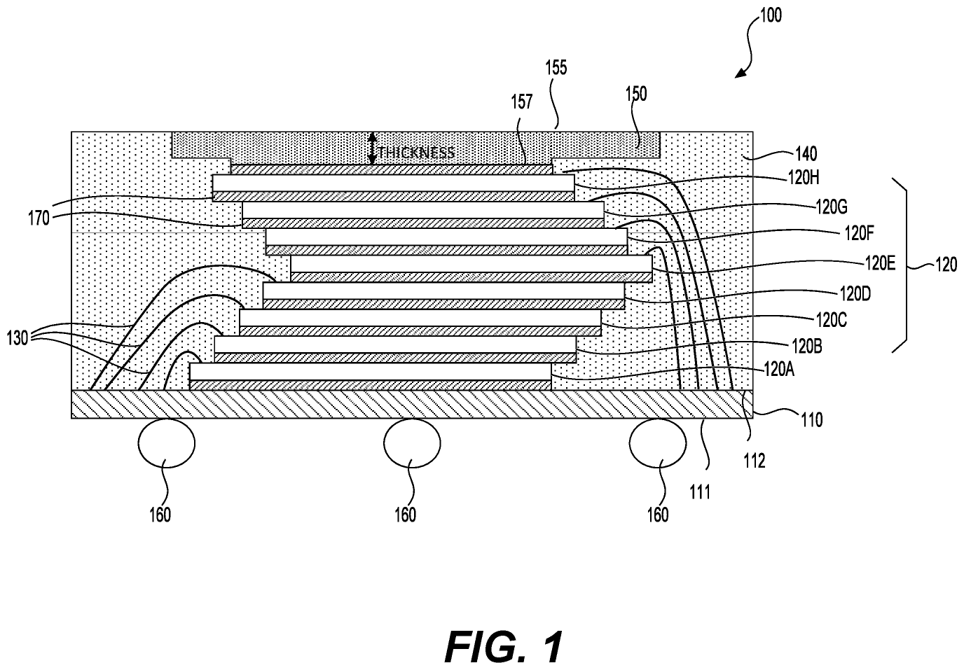

FIG. 1 shows a cross-sectional view of an integrated circuit (IC) package 100 in accordance with some embodiments. The IC package 100 includes a package substrate 110, a plurality of IC chips 120 (e.g., including IC chips 120A-120H in FIG. 1 example) and a marking plate 150. The IC chips 120 are stacked on the package substrate 110 and are encapsulated in a plastic structure 140. The marking plate 150 is stacked on the IC chips 120 and is embedded in the plastic structure 140. A surface 155 of the marking plate 150 is a portion of the outer surface of the IC package 100 and the surface 155 can be laser-marked for identification and traceability.

The package substrate 110 is made, for example, of suitable insulating material (also referred to as dielectric material), such as an epoxy based laminate substrate, a resin-based Bismaleimide-Triazine (BT) substrate, and the like. The package substrate 110 is relatively rigid to provide mechanical support to the IC chips 120. The package substrate 110 has a first surface 111 and a second surface 112. The IC chips 120 are disposed on a surface, such as the second surface 112 of the package substrate 110.

The package substrate 110 also provides electrical support for the IC chips 120. In some examples, the package substrate 110 includes multiple layers of metal traces, such as copper wires, and the like with the insulating material in between. The metal traces on the different layers can be connected by vias. Further, contact structures are formed on both the first surface 111 and the second surface 112 to electrically interface the IC chips 120 in the IC package 100 to components out of the IC package 100.

The IC chips 120 can be any suitable chips. The IC chips 120 include various circuits for providing storage, computing and/or processing functionalities.

The package substrate 110 provides interconnects from the inputs/outputs of the IC chips 120 to the contact structures that are formed on the first surface 111 and the second surface 112 of the IC package 100. In an example, the IC chips 120 includes input/output (I/O) pads (not shown) that are electrically connected to internal circuits that are formed on the IC chips 120. Bond wires 130 (e.g. aluminum wires, copper wires, silver wires, gold wires and the like) are bonded to connect the I/O pads on the IC chips 120 and the contact structures on the second surface 112 of the package substrate 110 to form electrical connections between the IC chips 120 and the package substrate 110. In the FIG. 1 example, neighboring IC chips in the IC chips 120 are staggered to provide bonding space to allow the bond wires 130 to be bonded on the I/O pads, and avoid shorting circuit. Further, the IC chips 120 are stacked in a zig-zag pattern to provide space for bond wires 130.

The package substrate 110 also includes suitable contact structures 160 on the first surface 111. In the FIG. 1 example, the IC package 100 is a ball grid array (BGA) package, and each of the contact structures 160 includes a solder pad and a solder ball that is deposited on the solder pad. It is noted that, in some examples, the solder balls are not formed on the package substrate 110. In an example, the IC package is a quad-flat package (QFP). In another example, the IC package 100 is a quad flat non-lead (QFN) package. In another example, the IC package 100 is a land grid array (LGA) package, and each of the contact structures includes a solder pad. In another embodiment, the IC package 100 is a pin grid array (PGA) package, and each of the contact structures 160 includes a pin.

In the FIG. 1 example, the package substrate 110, the plastic structure 140 and the marking plate 150 form the outer portion of the IC package 100 that encapsulates the IC chips 120 inside. Specifically, the marking plate 150 is stacked on the IC chips 120. Then, the second surface 112 of the package substrate 110, the IC chips 120 and the bond wires 130 are encapsulated by the plastic structure 140. The marking plate 150 is embedded in the plastic structure 140 with the surface 155 exposed for laser-marking.

The plastic structure 140 is formed of any suitable material, such as silica fillers, resin, and the like. In an example, the plastic structure 140 includes epoxy molding compound (EMC). The plastic structure 140 and IC chips 120 have different coefficient thermal expansions (CTE) (also referred to as CTE mismatch), and have different thermal conductivity.

According to an aspect of the disclosure, the marking plate 150 is formed of a material that has a higher rigidity than the plastic structure 140. In the FIG. 1 example, the IC package 100 includes the marking plate 150, the IC chips 120 and the package substrate 110 from the upper surface (e.g., the surface 155 of the marking plate 150) to the bottom surface (e.g., the first surface 111 of the package substrate 110). The marking plate 150, the IC chips and the package substrate 110 have relatively high rigidity than the plastic structure 140. In a conventional example, the upper portion of a related IC package is also made of EMC, and is used for later-marking. Compared to the conventional example, the IC package 100 has lower volume percentage of EMC, and thus has higher package rigidity than the conventional example.

According to another aspect of the disclosure, the marking plate 150 has about the same CTE (e.g., matching CTE) as the IC chips 120. Thus, the IC package 110 has a reduced warpage during thermal processing. For example, CTE mismatch can cause package warpage during thermal processing after molding. For example, the IC packages can be mounted on a printed circuit board (PCB) using a surface mount process. The surface mount process includes a solder reflow step that raises a processing temperature, for example, above 200° C. When the processing temperature returns to for example room temperature, the IC package 100 has reduced warpage compared to the conventional example due to the matching CTE from the upper surface to the bottom surface.

Further, according to an aspect of the disclosure, the marking plate 150 has a better anti-laser penetration property than the plastic structure 140 to prevent laser penetration. For example, a laser penetration depth in the marking plate 150 is shorter than a laser penetration depth in the plastic structure 140. Thus, the IC package 100 has a reduced thickness or can include more IC chips 120. For example, in the conventional example, because the laser-marking is marked on the EMC, to prevent laser damages to the circuits on the IC chips 120 and to the bond wires 130, the top portion of the plastic package above the IC chips needs to be relatively thick, such as about 150 μm. The marking plate 150 has a better anti-laser penetration property than the plastic structure 140, and a thickness of 30 μm is enough to prevent laser damage to the circuits on the IC chips 120 and the bond wires 130.

According to another aspect of the disclosure, the marking plate 150 has a better thermal conductivity than the plastic structure 140. For example, the marking plate 150 can transfer heat generated by the IC chips during operation to the outer surface of the IC package 100 faster than the plastic structure 140. The fast heat transfer can provide proper thermal environment for the IC chips 120, reduce chip temperature during operation, and allow the IC chips 120 to perform properly during operation.

In an embodiment, the marking plate 150 is form of silicon, such as pure silicon, and is then referred to as a mirror die (due to shining surface 155) in an example. Thus, the marking plate 150 has about the same CTE (e.g., matching CTE) as the IC chips 120, and has a higher rigidity and better anti-laser penetration property than the plastic structure 140.

It is noted that other suitable material, such as ceramic, metal, metal alloy can be used to form the marking plate 150. In an example, the marking plate 150 is formed of ceramic material. In another example, the marking plate 150 is formed of metal alloy. The marking plate 150 is suitably processed such that the bottom surface of the marking plate 150 that faces the IC chips 120 is electrically non-conductive to avoid shorting to the bond wires 130.

In the FIG. 1 example, the marking plate 150 is configured to have a stair shape at the cross-sectional view. Thus, the surface 157 of the marking plate 150 that faces the IC chip 120H is smaller than the surface 155 of the marking plate 150. The smaller surface 157 provides more space for wire-bonding on the IC chip 120H. The larger surface 155 allows more area for laser markings.

It is noted that while the IC chips 120 are shown with the same chip size in FIG. 1 example, the IC chips 120 can have different chip sizes in other examples.

It is also noted that when stacking IC chips 120 and the marking plate 150, intermediate layers 170, such as adhesive films, polymer films, spacer films, and the like can be used between the IC chips 120 and the marking plate 150.

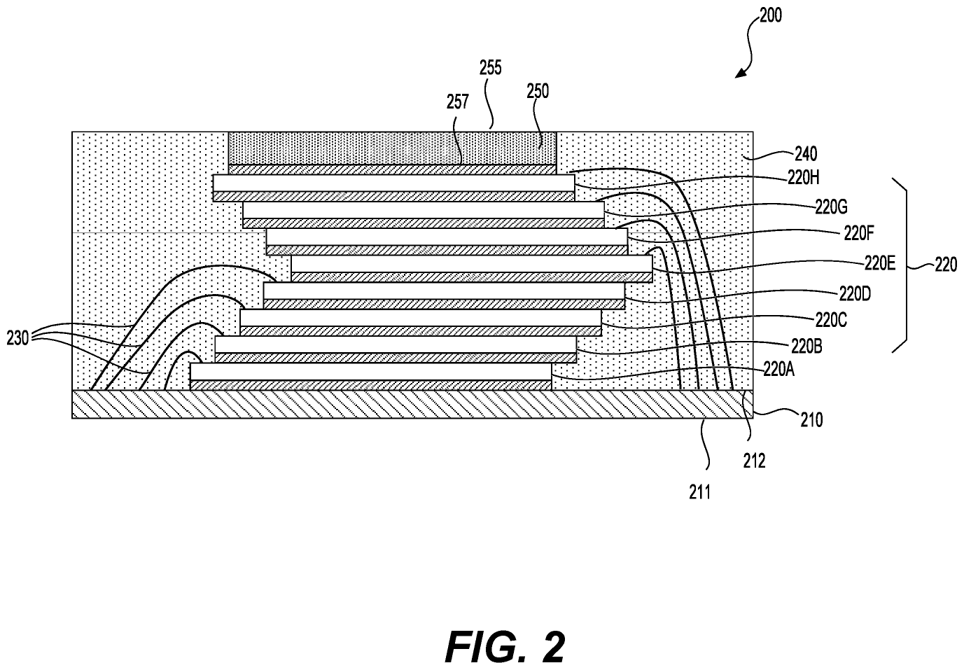

FIG. 2 shows a cross-sectional view of another IC package 200 in accordance with some embodiments. Similar to the IC package 100, the IC package 200 includes a package substrate 210, a plurality of IC chips 220 and a marking plate 250. The IC chips 220 are stacked on the package substrate 210 and are encapsulated in a plastic structure 240. The marking plate 250 is stacked on the IC chips 220 and is embedded in the plastic structure 240. A surface 255 of the marking plate 250 is a portion of the outer surface of the IC package 200 and the surface 255 can be laser-marked for identification and traceability.

The IC package 200 utilizes certain components that are identical, equivalent or similar to those used in the IC package 100. For example, the IC chips 220 are equivalent or similar to the IC chips 120. The bond wires 230 are equivalent or similar to the bond wires 130. The plastic structure 240 is equivalent or similar to the plastic structure 140. The package substrate 210 is equivalent or similar to the package substrate 110. The description of these components has been provided above and will be omitted here for clarity purposes.

In the FIG. 2 example, the marking plate 250 is configured to have a rectangular cuboid shape, and have a rectangular shape in the cross-sectional view, thus the surface 257 that faces the IC chip 220H is of the same surface area as the surface 255 that is a portion of the outer surface of the IC package 200.

Further, in the FIG. 2 example, the IC package 200 can be a LGA package without soldering balls. The package substrate 210 includes flat contact structures on the first surface 211.

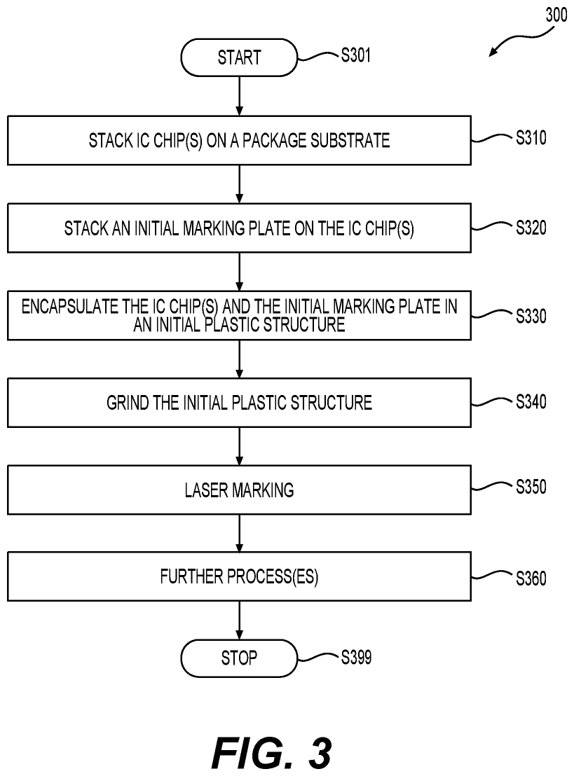

FIG. 3 shows a flow chart outlining a process 300 for fabrication according some embodiments of the disclosure. In an example, the process 300 is used to fabricate an IC package, such as the IC package 100, the IC package 200, and the like.

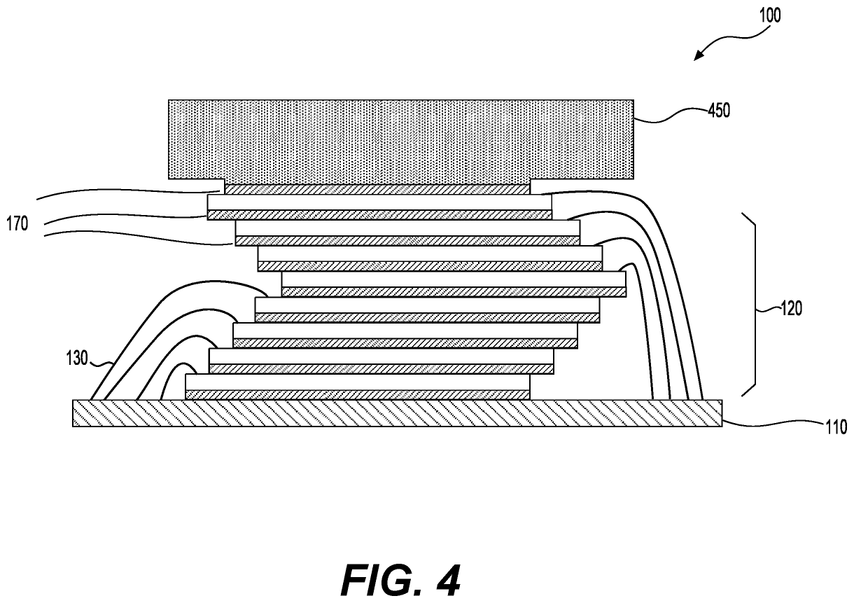

FIGS. 4-6 show various cross sectional views of the IC package 100 at intermediate stages during the process 300 in accordance with some embodiments. It is noted that suitable modifications can be made on the FIGS. 4-6 for other IC package, such as the IC package 200.

Referring to FIG. 3 and FIG. 4, the process starts at S301, and proceeds to S310.

At S310, IC chips are stacked on a package substrate. As shown in FIG. 4, the plurality of IC chips 120 are stacked on the package substrate 110. The IC chips 120 are stacked in a staggered manner to provide more space for wire bonding. For example, neighboring IC chips in the IC chips 120 area staggered to provide space for wire bonding. The IC chips 120 can be stacked in a zig-zag pattern. Then bond wires 130 are bonded to interconnect the IC chips 120 to the package substrate 110. In the FIG. 4 example, adhesive films 170 are used between the neighboring IC chips 120.

At S320, an initial marking plate is stacked on the IC chips. As shown in FIG. 4, an initial marking plate 450 is stacked on the IC chips 120. It is noted that the initial marking plate 450 is thicker than the marking plate 150 in the IC package 100. In the FIG. 4 example, an adhesive film 170 is used between the initial marking plate 450 and the top of IC chips 120.

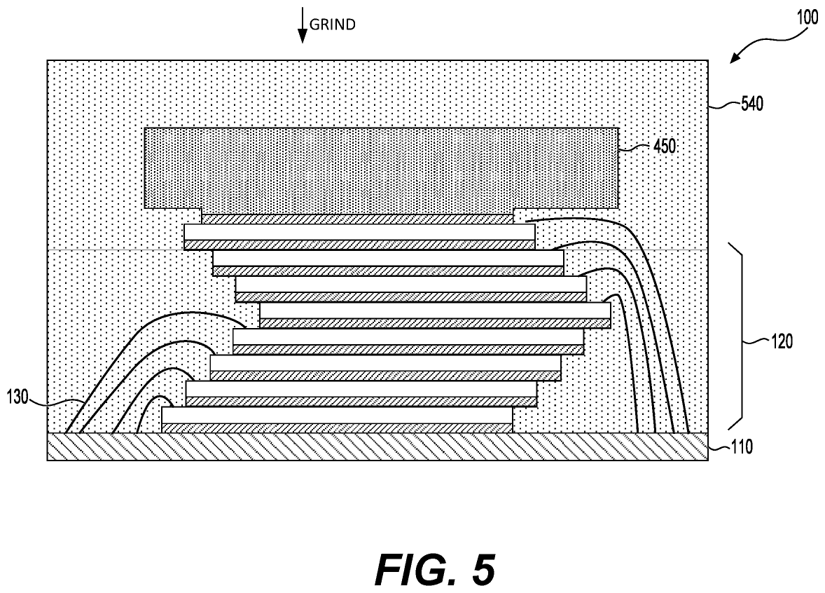

At S330, the initial marking plate and the IC chips are encapsulated in an initial plastic structure. As shown in FIG. 5, plastic material, such as EMC and the like is molded to form the initial plastic structure 540 that encapsulates the IC chips 120 and the initial marking plate 450.

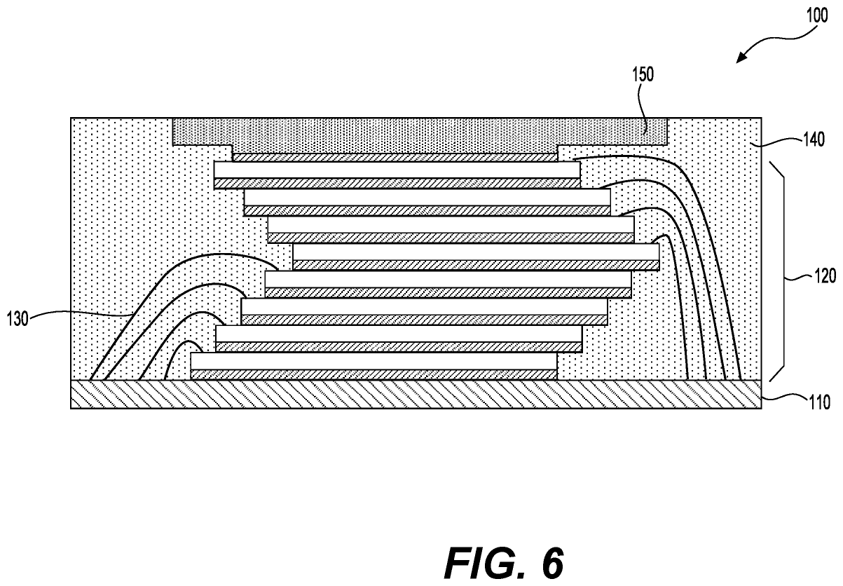

At S340, the initial plastic structure is grinded. As shown in FIG. 5, the initial plastic structure 540 is grinded to expose the initial marking plate 450, and further grinded to form the plastic structure 140 and the marking plate 150. FIG. 6 shows the IC package after the grinding process.

At S350, the IC package is laser marked on the marking plate. For example, later marking can be performed on the marking plate 150 for identification and traceability.

At S360, further process(es) can be performed on the IC package. In an example, solder balls, such as the solder balls 160 are attached to the package substrate 110. In an example, the IC packaging is performed in the form of a matrix array of packages. The matrix array of packages can be diced to form individual IC packages. The individual IC packages can then be tested and sorted. Then, the process proceeds to S399 and terminates.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating an integrated circuit (IC) package, comprising:
stacking one or more IC chips on a package substrate;
forming a marking plate on the one or more IC chips with a first major surface facing the one or more IC chips; and
forming a plastic structure that encapsulates the one or more IC chips and the marking plate with a second major surface of the marking plate being a portion of an outer surface of the IC package.

2. The method of claim 1, wherein
the forming the plastic structure further includes encapsulating an initial marking plate and the one or more IC chips in an initial plastic structure, the initial making plate being stacked on the one or more IC chips and having a first major surface facing the one or more IC chips and a second major surface opposite to the first major surface, and
grinding the initial plastic structure to expose the second major surface of the initial marking plate; and
the forming the marking plate includes grinding the second major surface of the initial marking plate.

3. The method of claim 1, further comprising:
laser-marking the second major surface of the marking plate.

4. The method of claim 1, wherein the forming the marking plate on the one or more IC chips further comprises:
forming the marking plate with the first major surface that is smaller than the second major surface facing the one or more IC chips.

5. The method of claim 1, before the plastic structure is formed, further comprising:
bonding wires between the one or more IC chips and the package substrate to interconnect the one or more IC chips to the package substrate.

6. The method of claim 1, wherein the stacking the one or more IC chips on the package substrate further comprises:
staggering neighboring IC chips in the one or more IC chips to provide space for bond wires.

7. The method of claim 1, wherein the forming the marking plate on the one or more IC chips further comprises:
forming the marking plate having a rectangular cuboid shape such that the first major surface and the second major surface have a substantially same surface area.

8. The method of claim 7, wherein:
a laser penetration depth in the marking plate is shorter than a laser penetration depth in the plastic structure.

9. The method of claim 1, wherein:
the marking plate has a higher rigidity than the plastic structure.

10. The method of claim 1, wherein:
the marking plate has a substantially equal coefficient thermal expansion (CTE) as the one or more IC chips.

11. A method for fabricating an integrated circuit (IC) package, comprising:
stacking one or more IC chips and a plurality of intermediate layers on a package substrate alternatingly such that each of the one or more IC chips is positioned between two adjacent intermediate layers of the plurality of intermediate layers;
forming a marking plate on the one or more IC chips with a first major surface facing the one or more IC chips and a second major surface opposite to the first major surface; and
forming a plastic structure that encapsulates the one or more IC chips and the marking plate such that the second major surface of the marking plate is a portion of an outer surface of the IC package, wherein:
the marking plate has one of a T-shaped cross-section and a rectangular-shaped cross-section in the plastic structure, the one of the T-shaped cross-section and the rectangular-shaped cross-section being perpendicular to a surface of an uppermost IC chip of the one or more IC chips closest to the marking plate.

12. The method of claim 11, wherein the T-shaped cross-section of the marking plate has a first dimension of the first major surface and a second dimension of the second major surface, the first dimension being less than the second dimension.

13. The method of claim 11, wherein the rectangular-shaped cross-section of the marking plate has a first dimension of the first major surface and a second dimension of the second major surface, the first dimension being approximately equal to the second dimension, the first and second dimensions being less than a third dimension of the surface of the uppermost IC chip such that two ends of the uppermost IC chip are not covered by the marking plate.

14. The method of claim 11, wherein
the forming the plastic structure further includes
encapsulating an initial marking plate and the one or more IC chips in an initial plastic structure, the initial making plate being stacked on the one or more IC chips and having a first major surface facing the one or more IC chips and a second major surface opposite to the first major surface, and
grinding the initial plastic structure to expose the second major surface of the initial marking plate; and
the forming the marking plate includes grinding the second major surface of the initial marking plate.

15. The method of claim 11, further comprising:
laser-marking the second major surface of the marking plate.

16. The method of claim 11, further comprising:
stacking the one or more IC chips and the plurality of intermediate layers on the package substrate in a staircase configuration such that each of the one or more IC chips have an end uncovered by an overlying IC chip;
bonding wires between the one or more IC chips and the package substrate to interconnect the one or more IC chips to the package substrate; and
forming the plastic structure that encapsulates the bonded wires.

17. The method of claim 11, wherein a laser penetration depth in the marking plate is shorter than a laser penetration depth in the plastic structure.

18. The method of claim 11, wherein the marking plate has a higher rigidity than the plastic structure.

19. The method of claim 11, wherein the marking plate has a substantially equal coefficient thermal expansion (CTE) as the one or more IC chips.

20. The method of claim 11, wherein the marking plate is configured to increase a rigidity of the IC package and reduce a thickness of the plastic structure.
